(19) United States
(12) Patent Application Publication
(10) Pub. No.: US 2005/0263843 A1
(43) Pub. Date: Dec. 1, 2005

(54) Semiconductor device and fabrication method therefor

(75) Inventor: Kiyohiko Sakakibara, Hyogo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 11/137,639

(22) Filed: May 26, 2005

(30) Foreign Application Priority Data
May 27, 2004 (JP) 2004-157909 (P)
Apr. 26, 2005 (JP) 2005-128171 (P)

(51) Int. Cl. H01L 29/00; H01L 21/336

(52) U.S. Cl. 257/500; 438/218; 438/294

(57) ABSTRACT

A high withstand voltage well is formed on a surface of a semiconductor substrate. A drain region and a source region of a high withstand voltage transistor included in an input protection circuit are formed on the high withstand voltage well. A p-type impurity region is formed adjacent to the lower portion of the drain region of the high withstand voltage transistor. The p-type impurity region is fabricated in the same fabrication step as a low withstand voltage well formed in a region on which a low withstand voltage transistor is formed.

### BACKGROUND OF THE INVENTION

1. Field of the Invention

The invention relates to a semiconductor device and a fabrication method therefor, and in particular, to a semiconductor device having an input protection circuit disposed between an input/output terminal and an internal circuit and a fabrication method therefor.

2. Description of the Background Art

A case arises where an excessively high voltage (a surge voltage) beyond a withstand voltage of an internal circuit is applied to an input/output terminal of a semiconductor device by static electricity. If an excessively high voltage is applied directly to the internal circuit, the internal circuit is broken down.

In order to prevent breakdown of the internal circuit, the input protection circuit has been provided between the input/output terminal and the internal circuit. With the input protection circuit adopted, when an excessively high voltage is applied to the input/output terminal, a current flows into the input protection circuit from the input/output terminal to thereby prevent the internal circuit from suffering excessively high voltage applied thereto.

Such an input protection circuit is disclosed, for example, in Japanese Patent Laying-Open No. 2004-015003. Disclosed in the publication is of a construction that a p-type diffusion region is formed so as to be in contact with the lower portion of the n-type drain region of an n channel MOS (Metal Oxide Semiconductor) transistor included in input protection circuit. The p-type diffused region is formed in the same fabrication step as a p type pocket region formed in contact with the source/drain regions of a low withstand voltage transistor as an internal element.

Transistors constituting an input protection circuit is fabricated simultaneously with transistors constituting a peripheral circuit for the purposes to prevent increase in fabrication steps and to realize a low cost. In many cases, peripheral transistors are divided into two kinds of a high withstand voltage type and a low withstand voltage type. This is because while a voltage supplied from outside a semiconductor device is in the range of from 3 to 5 V, a voltage used inside the semiconductor device is at 2.5 V or 1.8 V, or lower than those by stepping down the supplied voltage with a voltage down converter (VDC) from the viewpoint of device operating characteristics (such as a high speed operation and down-sized circuit area).

Transistors constituting an input protection circuit are all of a high withstand voltage type. This is for the purpose to overcome a break-down voltage of a gate oxide film. In a high withstand voltage transistor as well, a progress has been made toward a gate oxide thinner film and a substrate with a higher concentration for miniaturization in design of an MOS transistor and suppression of a short channel effect. Hence, a case arises where a minute leakage current occurs in a transistor of the input protection circuit after application of a surge voltage to an input/output terminal. Such an increase in minute leakage current has been problematic because of raised power consumption during standby.

Since, in the protection circuit disclosed in the publication, a p type diffused region below the drain region of the NMOS transistor is fabricated in the same fabrication step as the p-type pocket region, the p-type impurity region is formed so as to reach as far as the side end portion region of the drain region located on the gate electrode side of the nMOS transistor. Hence, a concentration of a p-type impurity in the vicinity of the side end portion region of the drain region gets higher, which lowers a junction withstand voltage of the side end portion region. Thus, it is difficult to suppress the minute leakage current mentioned above.

In the protection circuit disclosed in the publication, since the p-type diffused region in contact with the lower portion of the n-type drain region of the nMOS transistor constituting the protection circuit is fabricated in the same fabrication step as the p-type pocket region of the low withstand voltage transistor, a construction cannot be adopted that the low withstand transistor has no p-type pocket. Even if the low withstand voltage transistor is applied to a construction without a p-type pocket region, a special fabrication step for forming the p-type diffused region is required, which makes a fabrication process complicated with difficulty of reduction in cost.

### SUMMARY OF THE INVENTION

The invention has been made in order to solve the task as described above and it is an object of the invention to provide a semiconductor device capable of suppressing occurrence of a minute leakage current. It is another object of the invention to provide a fabrication method for a semiconductor device capable of fabricating in a simple and easy process and suppressing occurrence of a minute leakage current.

A semiconductor device of the invention is directed to a semiconductor device having an input protection circuit disposed between an input/output terminal and an internal circuit, and includes: a first conductivity type substrate having a main surface; a high withstand voltage transistor, included in the input protection circuit, formed on the main surface of the substrate, and having the source region and drain region of a second conductivity type; and a low withstand voltage transistor, included in the internal circuit, formed on the main surface of the substrate, and having the source region and drain region of the second conductivity type. The drain region of the high withstand voltage transistor has a side end portion region located on the gate electrode side of the high withstand voltage transistor and a lower portion region spaced from the gate electrode more than the side end portion region, and a junction withstand voltage between a first conductivity type first region adjacent to the lower portion region and the lower portion region is reduced to a value lower than a junction withstand voltage between a first conductivity type second region adjacent to the side end portion region and the side end portion region.

Another semiconductor device of the invention includes: a first conductivity type substrate having a main surface; a high withstand voltage transistor included in an input protection circuit, formed on the main surface of the substrate, and having the source region and drain region of a second conductivity type; a low withstand voltage transistor, included in an internal circuit, and having the source region and drain region of the second conductivity type formed on the main surface of the substrate; and a first conductivity type impurity region adjacent to the drain region of the high withstand voltage transistor. The drain region of the high withstand voltage transistor has a side end portion region located on the gate electrode side of the high withstand voltage transistor and a lower portion region spaced from the gate electrode more than the side end portion region. A concentration of a first conductivity type impurity included in the impurity region is higher than a concentration of the first conductivity impurity included in a first conductivity type region adjacent to the side end portion region and the impurity region is formed so as to be adjacent to the lower portion region without reaching the side end portion region. An end portion of the impurity region located on the gate electrode side of the high withstand transistor is isolated from the gate electrode of the high withstand transistor so as not to overlap the gate electrode thereof.

Still another semiconductor device of the invention is directed to a semiconductor device having an input protection circuit disposed between an input/output terminal and an internal circuit and includes: a substrate; a first conductivity type first well; a first conductivity type second well; a high withstand voltage transistor; a low withstand voltage transistor; and a first conductivity type impurity region. The substrate has a main surface. The first conductivity type first well is formed on the main surface of the substrate. The first conductivity type second well is formed on the main surface of the substrate and a concentration of the first conductivity type impurity is higher than in the first well. The high withstand voltage transistor has the source region and drain region of the second conductivity type formed in the first well and is included in the input protection circuit. The low withstand voltage transistor has the source region and drain region of the second conductivity type formed in the second well and is included in the internal circuit. The first conductivity type impurity region is formed in the same fabrication step as the second well so as to be adjacent to the lower portion of the drain region of the high withstand voltage transistor.

Yet another semiconductor device of the invention is directed to a semiconductor device having an input protection circuit disposed between an input/output terminal and an internal circuit, and includes: a substrate; a first conductivity type first well; and a high withstand voltage transistor. The substrate has a main surface. The first conductivity type first well is formed on the main surface of the substrate. The high withstand voltage transistor has the source region and drain region of a second conductivity formed in the first well and is included in the input protection circuit. The source region of the high withstand voltage transistor has a second conductivity type high concentration region formed on the main surface of the substrate and a low concentration region, adjacent to side and lower portions of the high concentration region, and surrounding the high concentration region. The drain of the high withstand voltage transistor has the second conductivity type high concentration region formed on the main surface of the substrate and the low concentration region adjacent only to the side and lower portions of an end portion of the high concentration region on the source side thereof.

A fabrication method for a semiconductor device of the invention is directed to a fabrication method for a semiconductor method having an input protection circuit disposed between an input/output terminal and an internal circuit, and includes the following steps:

A first conductivity type first well is at first formed on a main surface of a substrate. Not only is a first conductivity type second well higher in concentration of a first conductivity type impurity than in the first well, but a first conductivity type impurity region is also formed in the first well in the same fabrication step as the second well. The source and drain regions of a second conductivity type of a low withstand voltage transistor included in the internal circuit are formed in the second well and the source and drain regions of the second conductivity type of a high withstand voltage transistor included in the input protection circuit are formed in the first well. The drain region of the high withstand voltage transistor is formed so that the first conductivity type region is adjacent to the lower portion of the drain region.

A second fabrication method for a semiconductor device of the invention is directed to a fabrication method for a semiconductor device having an input protection circuit disposed between an input/output terminal and an internal circuit, and includes the following steps:

A first conductivity type first well is at first formed on a main surface of a substrate. A gate electrode layer is formed on the main surface of the substrate with a gate insulating layer interposed therebetween. An impurity is introduced into the main surface of the substrate with the gate electrode layer as a mask to thereby form a pair of low concentration regions of a second conductivity type working as the source and drain regions of a high withstand voltage transistor included in the input protection circuit in the first well. A sidewall insulating layer is formed on the side surface of the gate electrode layer. An impurity is introduced into the main surface of the substrate with the gate electrode layer, the sidewall insulating layer and a mask pattern as a mask to thereby, form a pair of high concentration regions of the second conductivity type working as the source/drain regions in the first well. The high concentration region of the source region is formed so as to be surrounded with the low concentration region at the side and lower portions of the high concentration region. The high concentration region of the drain region is formed so as to be surrounded with the low concentration region only at the side and lower portions of an end portion on the source side of the high concentration region.

According to a semiconductor device of the invention, a junction withstand voltage of the lower region of the drain region of the high withstand voltage transistor in the input protection circuit can be lower than an junction withstand voltage of the side end portion region of the drain region located on the gate electrode side of the high withstand voltage transistor. Hence, when a surge voltage is applied, electron-hole pairs can be formed at a voltage lower than the gate end portion below the drain of the high withstand voltage transistor in the input protection circuit, thereby enabling occurrence of electron-hole pairs to be suppressed at the gate end portion. Moreover, a parasitic bipolar transistor can be turned on by electron-hole pairs generated at the lower voltage. Hence, carrier injection into the gate insulating layer of the input protection circuit can be suppressed, thereby enabling occurrence of a minute current to be prevented.

In the fabrication method for a semiconductor device of the invention, since the first conductivity type impurity region is formed in the same fabrication step as the second well, no special step for forming the impurity region is unnecessary to be added and it is only required to change a pattern of a mask when the second well is formed. Therefore, a semiconductor device capable of suppressing occurrence a minute leakage current can be fabricated in a simple and easy process.

In the second fabrication method for a semiconductor device of the invention, since the high concentration region of the drain is fabricated simultaneously in the same fabrication step as the high concentration region of the source, no special step is necessary to be added in order to form the high concentration region of the drain and it is only required to change a pattern of a mask when the high concentration region of the source is formed. Therefore, a semiconductor device capable of suppressing occurrence of a minute current can be fabricated in a simple and easy process.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit configuration in the vicinity of an input protection circuit of a semiconductor device in a first embodiment of the invention;

FIG. 2 is a schematic plan view showing a structure of an nMOS transistor included in the input protection circuit of a semiconductor device in a first embodiment of the invention;

FIG. 3 is schematic sectional views showing a high withstand voltage nMOS transistor included in the input protection circuit and a low withstand voltage nMOS transistor and a high withstand nMOS transistor included in an internal circuit, wherein a section view of the high withstand voltage nMOS transistor corresponds to a section taken along line III-III of FIG. 2;

FIGS. 4 to 8 are schematic sectional views showing a first, a second and a fourth to sixth steps of a fabrication method of the first embodiment of the invention;

FIG. 9A is a drawing showing a construction of an NMOS transistor exhibiting a state where a potential in a high withstand voltage well falls and FIG. 9B is a graph showing potentials at positions in the high withstand well;

FIG. 10 is a plan view of an input protection circuit showing regions where electron-hole pairs are generated, each distinguishing from the others;

FIG. 11 is a schematic sectional view showing a gate end portion of a drain;

FIG. 12 is a graph showing a potential along line XII-XII of FIG. 11;

FIG. 13 is a graph showing that a minute leakage current occurs after a surge voltage is applied, wherein the ordinate is assigned to a drain current of a protection circuit transistor and the abscissa is assigned to a drain voltage;

FIG. 14 is schematic sectional views of a high withstand voltage nMOS transistor included in an input protection circuit and a low withstand voltage nMOS transistor and a high withstand voltage NMOS transistor included in a internal circuit of a semiconductor device in a second embodiment of the invention, wherein a sectional view of the high withstand nMOS transistor included in the input protection circuit corresponds to a sectional view taken along line III-III of FIG. 2;

FIG. 15A is a graph showing an impurity concentration distribution on section taken along line of XVA-XVA of FIG. 14 and FIG. 15B is a graph showing an impurity concentration distribution on section taken along line of XVB-XVB of FIG. 14;

FIGS. 16 to 22 are schematic sectional views showing a first to seventh step of a fabrication method of the second embodiment of the invention; and

FIG. 23 is a graph for describing dependency on a gate voltage of a junction withstand voltage of a drain region.

### DESCRIPTION OF THE PREFERRED EMBODIMENTS

Based on the accompanying drawings, description will be given of embodiments of the invention below.

### First Embodiment

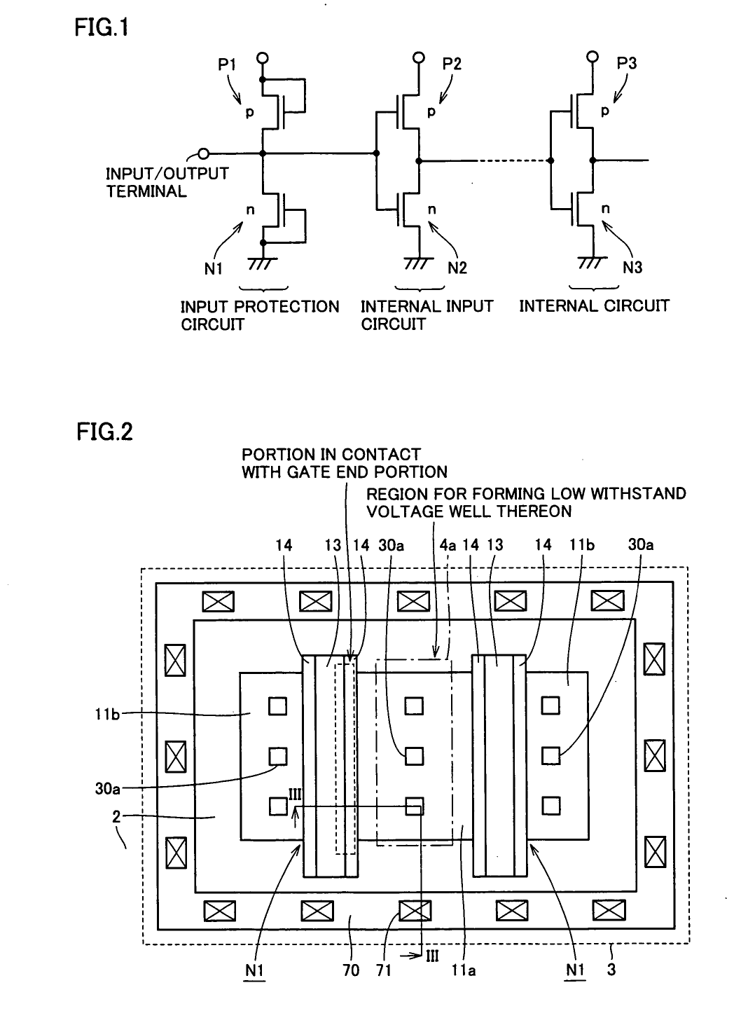

FIG. 1 is a circuit configuration in the vicinity of an input protection circuit of a semiconductor device in the first embodiment of the invention.

With reference to FIG. 1, an input protection circuit is disposed between an input/output terminal and an internal circuit. The input protection circuit is constituted of a CMOS (Complementary MOS) transistor circuit including, for example, an nMOS transistor N1 and a pMOS transistor P1. NMOS transistor N1 and pMOS transistor P1 are high withstand voltage transistors having a withstand voltage of 5 V or higher.

The source and gate of nMOS transistor N1 are electrically connected to a ground (GND) potential, the source and gate of pMOS transistor P1 are electrically connected to a power supply potential and the drains of nMOS transistor N1 and pMOS transistor P1 are electrically connected to each other.

The input/output terminal and the internal circuit both are electrically connected to the drains of nMOS transistor N1 and pMOS transistor P1. The input/output terminal is, for example, a bonding pad, the internal circuit has an internal input circuit and the internal input circuit includes an inverter constituted of an nMOS transistor N2 and pMOS transistor P2. NMOS transistor N2 and pMOS transistor P2 are high withstand voltage transistors having a withstand voltage of 5 V or higher.

The internal circuit includes a low withstand voltage lower in withstand voltage than the high withstand voltage transistors. The low withstand voltage transistor is a transistor driven, for example, by a power supply voltage of 3 V or lower. In the example of FIG. 1, there is illustrated a case of an internal circuit having an inverter constituted of nMOS transistor N3 and pMOS transistor P3 with a low withstand voltage.

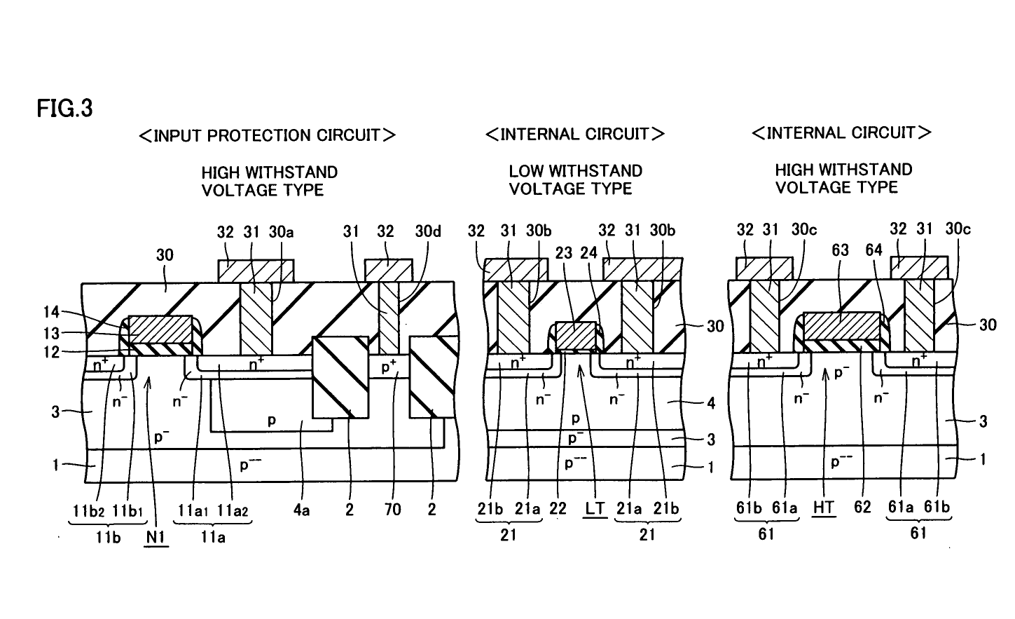

FIG. 2 is a schematic plan view showing a structure of an nMOS transistor included in the input protection circuit of a semiconductor device in a first embodiment of the invention. FIG. 3 is schematic sectional views showing a high withstand voltage nMOS transistor included in the input protection circuit and a low withstand voltage nMOS transistor and a high withstand voltage nMOS transistor included in an internal circuit, wherein a section view of the high withstand voltage nMOS transistor corresponds to a section taken along line III-III of FIG. 2.

With reference to FIG. 3, in a region forming a low withstand voltage LT included in an internal circuit therein, a p⁻ high withstand voltage well (first well) 3 having a p-type impurity concentration higher than a p⁻⁻ semiconductor substrate 1 formed on p⁻⁻ semiconductor substrate 1. A p type low withstand voltage well (second well) 4 higher in p-type impurity concentration than p⁻ high withstand well 3. A pair of n-type impurity regions working as the source region 21 and drain region 21, respectively, are formed on a surface of p-type low withstand voltage well 4. Each of source region 21 and drain region 21 has a high concentration region (n-type impurity region) 21b formed on the surface of semiconductor substrate and a low concentration region (n⁻ impurity region) 21a adjacent to the side portion and lower portion of high concentration region 21b and surrounding high concentration region 21b.

A gate electrode layer 23 is formed on a region sandwiched between a pair of n-type impurity regions 21 with a gate insulating layer (for example gate oxide film) 22 interposed therebetween. A sidewall insulating layer 24 is formed on the sidewall of gate electrode layer 23. Low withstand voltage transistor LT is constituted of pair of source/drain regions 21 and 21, gate insulating layer 22, sidewall insulating layer 24 and gate electrode layer 23.

An interlayer insulating layer 30 is formed so as to cover low withstand voltage transistor LT, and contact holes 30b extending to pair of source/drain regions 21 and 21 are formed through interlayer insulating layer 30. Filling layers (conductive layers: plug electrodes) 31 are formed in respective contact holes 30b. A conductive layer 32 is formed on interlayer insulating layer 30 so as to be electrically connected to source/drain regions 21 through filling layers 31, respectively.

On the other hand, in a region for forming high withstand voltage transistor HT thereon included in the internal circuit, p⁻ high withstand voltage well (first well) 3 having a p-type impurity concentration higher than p⁻⁻ semiconductor substrate 1 on p⁻ semiconductor substrate 1. P-type low withstand voltage well (second well) 4, however, is not formed on p⁻ high withstand voltage well 3. Hence, in a region for forming high withstand transistor HT thereon included in internal circuit, pair of n-type impurity regions working as source region 61 and drain region 61, respectively, are formed on a surface of p-type high withstand well 3. Source region and drain region 61 have, respectively, high concentration regions (n-type impurity region) 61b formed on surface of substrate and low concentration regions (n⁻ impurity regions) 61a adjacent to the side portion and lower portion of high concentration regions 61b, and surrounding high concentration 61b.

A gate electrode layer 63 is formed on a region sandwiched between pair of n-type impurity regions 61 with a gate insulating layer (for example, gate oxide film) 62 interposed therebetween. A sidewall insulating layer 64 is formed on the sidewall of gate electrode layer 63. High withstand voltage transistor LT is constituted of pair of source/drain regions 61 and 61, gate insulating layer 62, sidewall insulating layer 64 and gate electrode layer 63.

An interlayer insulating layer 30 is formed so as to cover high withstand voltage transistor LT, and contact holes 30c extending to pair of source/drain regions 61 and 61 are formed through interlayer insulating layer 30. Filling layer 31 is formed in contact holes 30c. A conductive layer 32 is formed on interlayer insulating layer 30 so as to be electrically connected to source/drain regions 61 through filling layer 31.

With reference to FIGS. 2 and 3, in a region for forming high withstand voltage NMOS transistor HT included in input protection circuit thereon, p⁻ high withstand voltage well 3 is formed on p⁻⁻ semiconductor substrate 1. Pair of n-type impurity regions working as drain region 11a and source region 11b are formed on surface of p⁻ high withstand voltage well 3. Drain region 11a and source region 11b include, respectively, high concentration regions (n-type impurity regions) 11a₂ and 11b₂ formed on surface of substrate 1 and low concentration regions (n⁻ impurity regions) 11a₁ and 11b₁ adjacent to the side portions and lower portions of high concentration regions 11a₂ and 11b₂ and surrounding high concentration regions 11a₂ and 11b₂.

Gate electrode layer 13 is formed on a region sandwiched between drain region 11a and source region 11b with gate insulating layer (for example gate oxide film) 12 interposed therebetween. Sidewall insulating layer 14 is formed on sidewall of gate electrode layer 13. High withstand transistor N1 is constituted of pair of source/drain regions 11a and 11b, gate insulating layer 12, sidewall insulating layer 14 and gate electrode layer 13.

A p-type impurity region 4a is formed so as to be adjacent to the lower portion of drain region 11a except source side end portion (gate lower side region positioned below the gate) of drain region 11a of high withstand transistor N1. P-type impurity region 4a is formed in the same fabrication step as a low withstand voltage well 4 and also the same as low withstand well 4 in a diffusion depth from substrate surface and an impurity concentration distribution in the depth direction.

A concentration of p-type impurity in p-type impurity region 4a is, for example, 5×10¹⁶ cm⁻³ or more and 5×10¹⁷ cm⁻³ or less and a peak of impurity concentration is located in the range of from 0.3 μm or more and 0.5 μm or less in the depth direction from surface of substrate 1 (the thickness direction of the substrate).

P-type impurity region 4a is formed at a region adjacent to the lower portion spaced more from gate electrode layer 13 than the side end portion region of drain region 11a located on gate electrode 13 side of high withstand transistor in input protection circuit. Since a concentration of p-type impurity included in p-type impurity region 4a is higher than a concentration of p-type impurity included in p⁻ high withstand well 3a, a junction withstand voltage between a region of p⁻ high withstand voltage well 3 adjacent to the lower portion of drain region 11a (a region in p-type impurity region 4a; first region) and the lower portion can be lower than a junction withstand voltage between a region (second region) in p⁻ high withstand voltage well 3 adjacent to the side end portion region of the drain region 11a and the side end portion region.

P-type impurity region 4a is formed so as to adjacent to the lower portion of drain region 11a without reaching to the side end portion region. An end portion of p-type impurity region 4a located on gate electrode layer 13 side of high withstand voltage transistor is, as shown in FIGS. 2 and 3, isolated from gate electrode layer 13 and sidewall insulating layer 14 so as not to overlap gate electrode layer 13 and sidewall insulating layer 14. For example, an end portion of p-type impurity region 4a located on gate electrode layer 13 side of high withstand voltage transistor is disposed at a site spaced apart from sidewall of gate electrode layer 13 on drain region 11a side by the order of 1 μm.

An annular p-type high concentration impurity region (guard ring region) 70 is, as shown in FIG. 2, formed so as to surround high withstand transistor N1. A concentration of p-type impurity included in p-type high concentration impurity region 70 is higher than a concentration of p-type impurity included in p-type impurity region 4a and it is, for example, on the order of 1×10¹⁸ cm⁻³ or more and 1×10¹⁹ cm⁻³ or less. A single or plural contact sections 71 are formed on p-type high concentration impurity region 70. In the example of FIG. 2, plural contact sections 71 are formed along all the periphery of high withstand voltage transistor N1. P-type high concentration impurity region 70 is connected to ground electrode through contact sections 71. With such a construction adopted, ground potential can be given to p-type high concentration impurity region 70.

Interlayer insulating layer 30 is formed so as to cover high withstand voltage transistor N1 and contact holes 30a extending downward to drain region 11a and source region 11b, respectively, are formed in interlayer insulating layer 30. Contact holes 30a are filled with filling layers 31. Conductive layer 32 is formed on interlayer insulating layer 30 so as to be electrically connected to drain region 11a and source region 11b through filling layers 31.

As shown in FIG. 3, contact hole 30d extending down to p-type high concentration impurity region 70 is formed in interlayer insulating layer 30 above p-type high concentration impurity region 70 and filling layer 31 is also formed in contact hole 30d. Conductive layer 32 is formed on filling layer 31 and conductive layer 32 is electrically connected to p-type high concentration impurity region 70 through filling layer 31. Ground potential is given to conductive layer 32 located above p-type high concentration impurity region 70 and filling layer 31 located above p-type high concentration impurity region 70 works as ground electrode giving ground potential to p-type high concentration impurity region 70.

The surface of semiconductor substrate 1 is electrically isolated by element isolation structures 2 (for example, field oxide film, trench isolation whose trench is filled with an insulating layer and the like). In the example of FIGS. 2 and 3, p-type high concentration impurity region 70 is formed between element isolation structures 2.

For example, a film thickness Tₒₓ of gate oxide film 22 of low withstand voltage transistor is 5.5 nm or less and a line width L_{g} of gate electrode layer 23 is 0.25 μm in a 0.25 μm design rule. For example, a film thickness Tₒₓ of gate oxide film 12 of high withstand voltage transistor with a withstand voltage of 5 V is 15 nm or less and a line width L_{g} of gate electrode layer 13 is 0.5 μm. In other words, as shown in FIG. 3, a thickness of gate insulating layer of high withstand voltage transistor is larger than that of gate insulating layer of low withstand voltage transistor, and gate electrode width of high withstand voltage transistor is larger than that of low withstand voltage transistor.

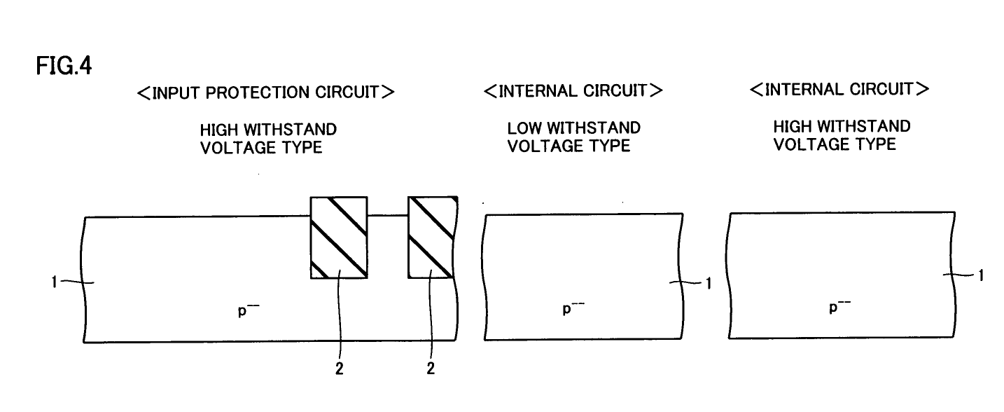

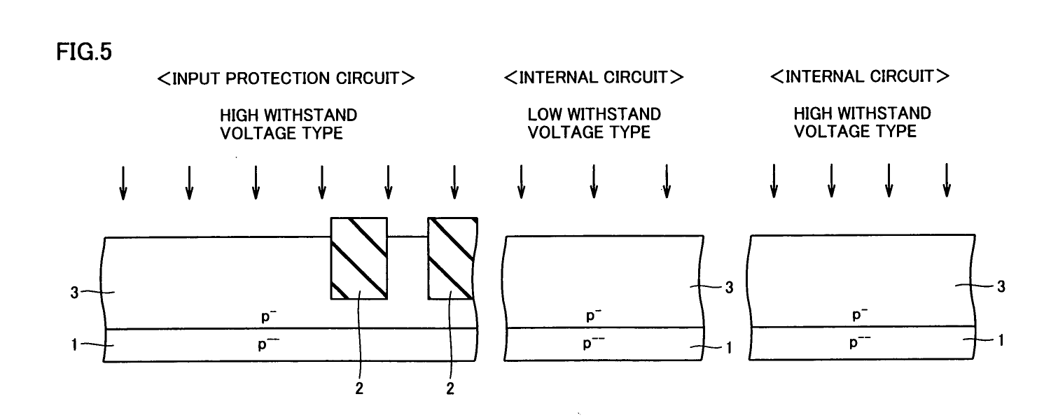

Then, with reference to FIGS. 4 to 8, description will be given of a fabrication method of the embodiment.

FIGS. 4 to 8 are schematic sectional views showing a fabrication method of the first embodiment of the invention in the order of step. With reference to FIG. 4, an element isolation structure 2 is formed on surface of p⁻⁻ semiconductor substrate 1.

With reference to FIG. 5, p⁻ high withstand voltage wells 3 are formed on regions for forming high withstand voltage transistor and low withstand voltage transistor, respectively, thereon. In a process for forming p⁻ high withstand voltage well 3, for example, boron (B) is ion implanted at an implantation energy in the range of from 70 to 120 keV and a dose of 2×10¹² cm⁻² or less to adjust a punch through effect and secure isolation ability and thereafter, boron is ion implanted at an implantation energy in the range of from 30 to 60 keV and a dose of 2×10¹² cm⁻² or less to adjust a threshold voltage.

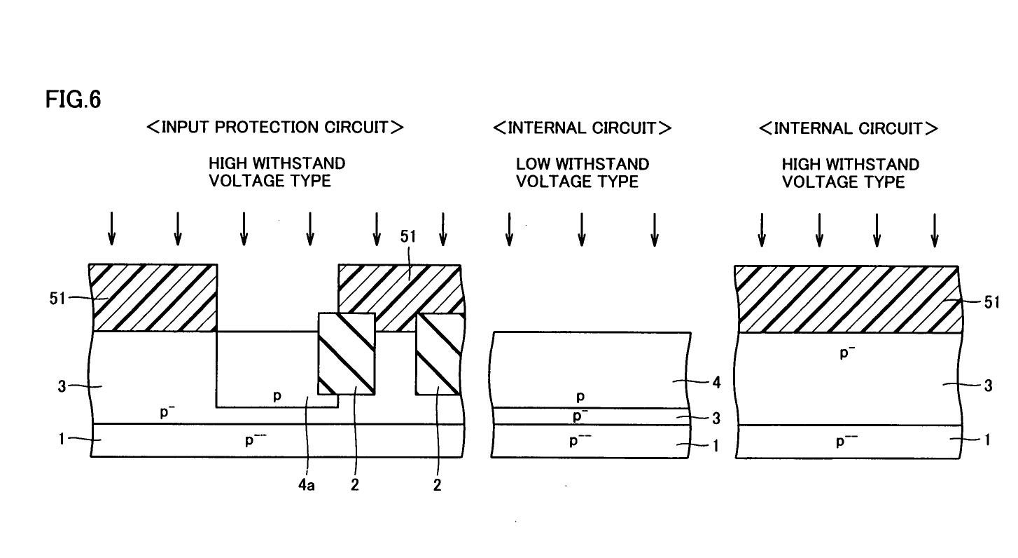

With reference to FIG. 6, a photoresist pattern (mask pattern) 51 is formed on semiconductor substrate 1 by means of a photolithography technique and a p-type impurity is introduced into semiconductor substrate 1, for example, by ion implantation with pattern 51 as a mask. Pattern 51 is patterned so as to cover at least a region for forming gate electrode layer 13 thereon to be formed in a later step. Pattern 51 is formed so that an edge portion of pattern 51 is located by a distance of the order of 1 μm apart from sidewall position on drain region 11a side of gate electrode layer 13 to be formed in a later step.

In the ion implantation step, p-type low withstand well 4 is formed in a region for forming low withstand transistor thereon and p-type impurity region 4a is formed in a region for forming high withstand voltage transistor thereon. In formation of low withstand voltage well 4 and p-type impurity region 4a, for example, boron (B) is ion implanted at an implantation energy in the range of from 70 to 120 keV and a dose of 3×10¹² cm⁻² or less to adjust a punch through effect and secure isolation ability and thereafter, boron is ion implanted at an implantation energy in the range of from 30 to 60 keV and a dose of 1×10¹³ cm⁻² or less to adjust a threshold voltage. Thereafter, pattern 51 is removed, for example, by ashing.

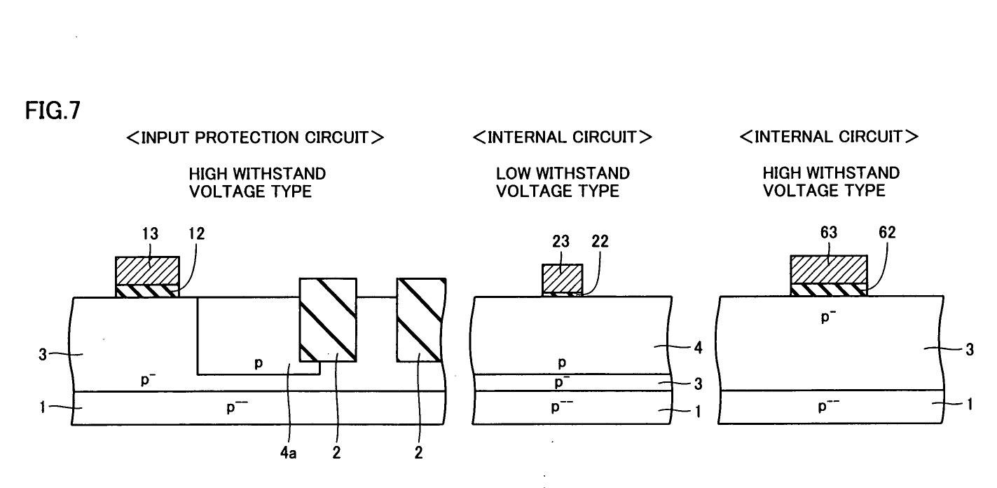

With reference to FIG. 7, gate electrode layers 13, 23 and 63 are formed on surface of semiconductor substrate 1 with gate insulating layers 12, 22 and 62 interposed therebetween in a region for forming low withstand transistor thereon and a region for forming high withstand voltage transistor thereon. In this step, in the example of FIG. 7, widths of gate electrode layers 13 and 63 of high withstand transistor are larger than a width of gate electrode layer 23 of low withstand transistor. Thickness values of gate insulating layers 12 and 62 of high withstand voltage transistor are larger than that of gate insulating layer 22 of low withstand voltage transistor.

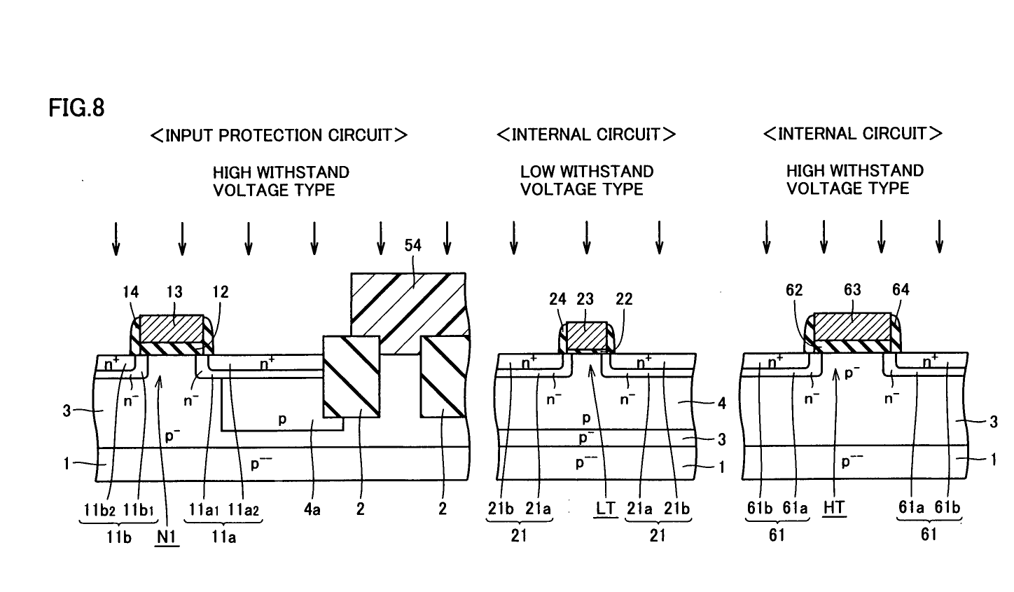

With reference to FIG. 8, n type impurity is introduced into semiconductor substrate 1, for example, by ion implantation with gate electrode layers 13, 23 and 63, and a photoresist pattern (a pattern in the shape similar to that of pattern of FIG. 8) not shown, formed by a photolithography process and covering a region for forming p-type high concentration impurity region 70 thereon as a mask. In this step, n-type low concentration regions 11a₁ and 11b₂ are formed in a region for forming protection circuit nMOS transistor thereon, n-type low concentration regions 21a and 21a are formed in a region for forming low withstand transistor of internal circuit thereon and n-type low concentration regions 61a and 61a are formed in a region for forming high withstand transistor thereon. Thereafter, the pattern is removed, for example, by ashing.

Note that in the example described above, description has been given of the case where low concentration regions 21a and 21a in a low withstand voltage side, low concentration regions 11a₁ and 11b₁ and low concentration regions 61a and 61a in a high withstand voltage side are formed simultaneously, the regions may be formed by different ion implantation steps. In the latter case, high withstand voltage type low concentration regions 11a₁ and 11b₁ and low concentration regions 61a and 61a are formed in a process in which, for example, phosphorus (P) is ion implanted at an implantation energy in the range of 20 to 50 keV and a dose of 1×10¹³ cm⁻² or more and 3×10¹³ cm⁻² or less, followed by a heat treatment for diffusion. In a case where low withstand type low concentration regions 21a and 21a are formed, for example, arsenic (As) is ion implanted at an implantation energy in the range of from 20 to 50 keV and at a dose of 1×10¹⁴ cm⁻² or more and 5×10¹⁴ cm⁻² or less.

Then, sidewall insulating layers 14, 24 and 64 are formed on the sidewall of gate electrode layers 13, 23 and 63. The sidewall insulating layer 14, 24 and 64 can be formed by means of a method of deposition of an insulating layer and etch-back combined. N-type impurity is introduced into semiconductor substrate 1, for example, by ion implantation with gate electrode layers 13, 23 and 63, sidewall insulating layers 14, 24 and 64 and a pattern 54, formed by a photolithography process or the like, and covering a region for forming p-type high concentration impurity region 70 thereon as a mask. In this step, n-type high concentration regions 11a₂ and 11b₂ are formed in a region for forming protection circuit nMOS transistor thereon, n-type high concentration region 21b and 21b is formed in a region for forming low withstand transistor of internal circuit thereon, n-type high concentration regions 61b and 61b are formed in a region for forming high withstand voltage transistor of internal circuit thereon. In formation of high concentration regions 11a₂ and 11b₂, high concentration regions 21b and 21b and high concentration regions 61b and 61b, for example, arsenic (As) is ion implanted at an implantation energy in the range of from 30 to 50 keV and a dose of 1×10¹⁵ cm⁻² or more and 5×10¹⁵ cm⁻² or less.

In this step, in regions for forming low withstand transistor and forming high withstand transistor of internal circuit thereon, low concentration regions 21a and 61a are formed adjacent to the side portions and lower portions of high concentration regions 21b and 61b and so as to surround the regions.

In a region for forming protection circuit nMOS transistor thereon, low concentration region 11b₁ is formed adjacent to the side portion and the lower portion of high concentration region 11b₂ and so as to surround the region, and low concentration region 11a₁ is formed adjacent to the side portion and the lower portion of high concentration region 11a₂ and so as to surround the region. As a result, in the first embodiment, p-type impurity region 4a is formed adjacent to low concentration region 11a₁. Thereafter, pattern 54 is removed, for example, by ashing.

Note that in the case of high concentration regions 11a₂, 11b₂, 21b and 61b as well, the regions may be formed simultaneously, but in different ion implantation steps. Thereafter, other elements such as pMOS transistor are formed. P-type high concentration impurity region 70 is formed in formation of p-type impurity regions such as the source/drain of pMOS transistor. Note that p-type high concentration impurity region 70 can also be formed before formation of NMOS transistor and pMOS transistor. After, in this way, various kinds of elements are formed on semiconductor substrate, interlayer insulating layer 30, filling layer 31, conductive layer 32 and others, shown in FIG. 3, are formed. The semiconductor device shown in FIG. 3 is completed through all the steps.

Then, description will be given of a mechanism of letting a surge voltage escape in input protection circuit in the embodiment.

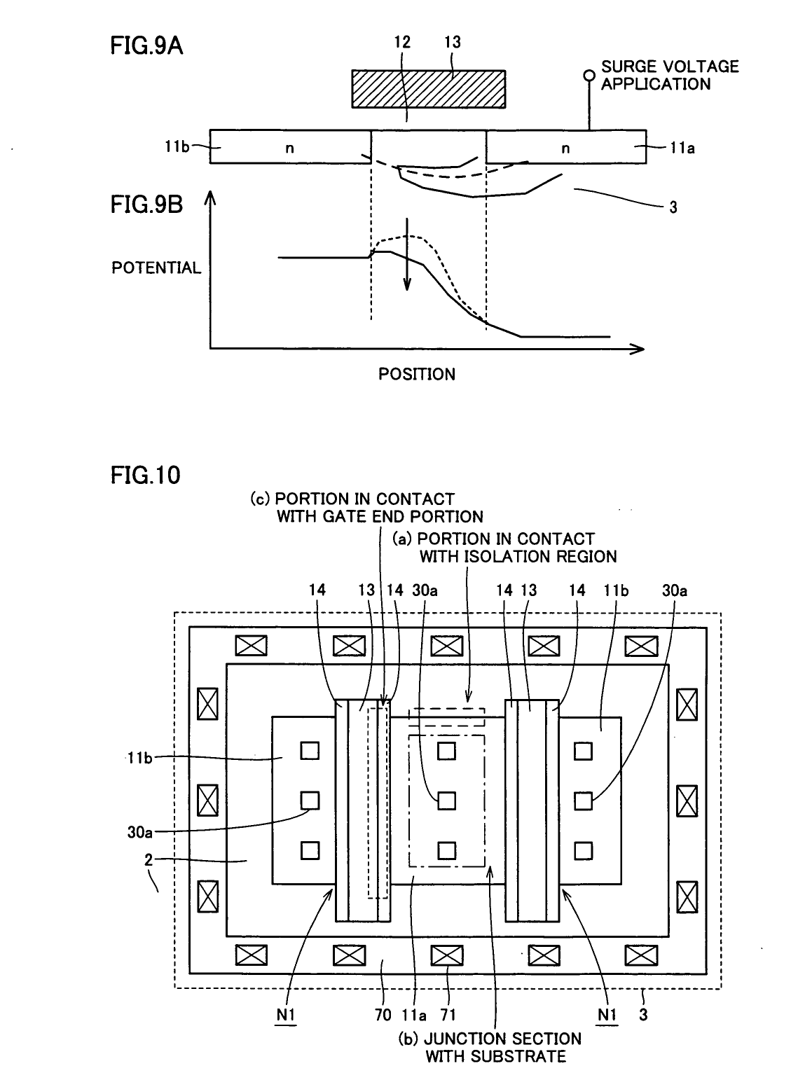

In a case where, in FIG. 1, a voltage surge (positive surge) is inputted to input/output terminal, a potential of drain region 11a of nMOS transistor N1 of input protection circuit shown in FIG. 3 is raised. As a result, a large potential gradient occurs between drain region 11a and p-type region (3 and 4a) in the vicinity thereof. Electron and hole pairs are formed by avalanche under the large potential gradient. Holes thus formed flow into high withstand well 3 and thereby, a potential of high withstand well 3 falls from a dotted line down to a solid line as shown in FIG. 9B. Since a potential of high withstand voltage well 3 falls between the source-drain, a punch through occurs in a parasitic bipolar transistor constituted of drain region 11a, high withstand voltage well 3 and source region 11b to enter a conductive state (ON state); therefore, a surge voltage escapes into GND (ground) line.

Note that FIG. 9A is a drawing of a construction of an nMOS transistor showing a state where a potential in a high withstand voltage well 3 falls and FIG. 9B is a graph showing potentials at positions in the high withstand well 3.

According to the embodiment, a construction can be formed in a simple easy process that a junction withstand voltage between the lower portion region of n-type drain region and p-type region can be reduced, a punch through in the parasitic transistor is caused with ease and occurrence of a minute leakage current can be suppressed. Description will be given thereof below.

Description will be given, at first, of a mechanism of an increase in minute current.

A problematic minute leakage current occurs according to a GIDL (Gate Induced Drain Leakage) mechanism.

With a surge voltage applied, a high electric field region arises in the vicinity of the gate/drain and electron-hole pairs are formed due to an avalanche breakdown. The electron-hole pairs arise at various positions of the drain junction. For example, as shown in FIG. 10 exhibiting a plan view of input protection circuit, electron-hole pairs arise in (a) junction section in contact with element isolation structure 2, (b) a junction section with substrate, and (c) an end portion region of gate electrode layer 13.

In general, a withstand voltage determined by a portion (c) in contact with the end portion of gate electrode 13 (gate end withstand voltage BVds) is lower than a withstand voltage (junction withstand voltage BVj) determined by isolation region (a) and substrate region (b). For example, gate end withstand voltage BVds of high withstand nMOS transistor class with a withstand voltage of 5V is 10.5 V and a junction withstand voltage BVj is 13V.

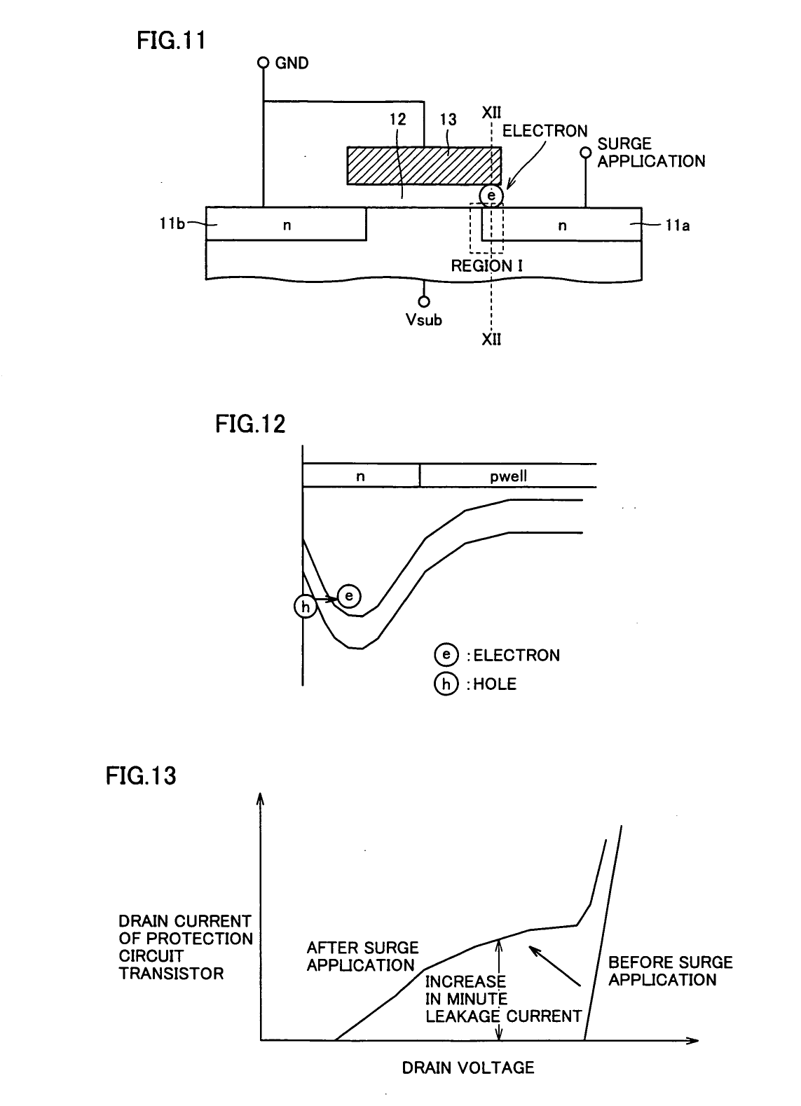

That is, electron-hole pairs mainly occur in the vicinity of the end portion of gate electrode layer in a transistor formed with a junction between a well of a transistor and the source/drain each of one kind. Of electron-hole pairs formed, for example, electrons are trapped in the end portion on drain region 11a side of gate electrode layer 13 of NMOS transistor N1 of input protection circuit as shown in FIG. 11a. In such a situation, in a case where a voltage is applied after a surge is applied, a high electric field region as shown in FIG. 12 arises inside drain region 11a in region 1 of FIG. 111 (a region where the junctions of gate electrode layer 13 and drain region 11a are overlapped one on the other in plan view, that is the junction of drain region 11a right below gate electrode layer 13) and electron-holes pairs arise due to electron tunneling from the valence band to the conduction band of silicon substrate. This is the GIDL mechanism. A minute leakage current occurs and increases as shown in FIG. 13 by contribution of electron holes pairs generated according to the GIDL mechanism.

Note that FIG. 12 is a graph showing a potential along line XII-XII of FIG. 11. FIG. 13 is a graph showing that a minute leakage current occurs after a surge voltage is applied.

In the embodiment, p-type impurity region 4a is, as shown in FIG. 3, adjacent to the lower portion of drain region 11a. P-type impurity region 4a is fabricated in the same fabrication step as low withstand voltage well 4 and a concentration of p-type impurity is higher than p⁻ high withstand voltage well 3. Hence, a withstand voltage can be reduced in a junction section between drain region 11a and p-type impurity region 4a. Hence, a withstand voltage of isolation region (a) and a withstand voltage (junction withstand voltage BVj) of substrate region (b) shown in FIG. 10 can be lower than a withstand voltage determined by a portion (c) in contact with the end portion of gate electrode layer 13. Hence, when a surge voltage is applied, electron-hole pairs can be generated in the junction section between drain region 11a and p-type impurity region 4a at a voltage lower than a withstand voltage of gate end portion, thereby enabling occurrence of electron-hole pairs in drain region 11a of gate end portion to be prevented. In addition, a parasitic bipolar transistor can be turned on with electron-hole pairs generated at the low voltage. Therefore, injection of carriers into gate insulating layer of input protection circuit can be suppressed with the result that occurrence of a minute current caused by the GIDL mechanism can be suppressed.

That is, miniaturization of a device is accompanied with increase in concentration in substrate of high withstand voltage transistor, which causes a surge voltage to be hard to be escaped, thereby enabling increase in minute current due to GIDL generated after a surge voltage is applied to be prevented. Note that a suppression effect on the minute leakage current can be conspicuous by fabricating p-type impurity region 4a so as not to reach the side end portion region of drain region 11a. The suppression effect on the minute leakage current can be more conspicuous by isolating the end portion of p-type impurity region 4a located on the gate electrode side of high withstand voltage transistor so as not to overlap gate electrode and sidewall insulating layer of high withstand voltage transistor.

Formation of p-type high concentration impurity region 70 enables a wrong influence of electron-hole pairs generated in the junction section between drain region 11a and p-type impurity region 4a on a device in the neighborhood of p-type high concentration impurity region 70 to be avoided. In addition, since exists high withstand voltage well 3 lower in concentration of a p-type impurity than p-type impurity region 4a direct below a channel formation region where a punch through actually arises, a depletion layer in high withstand well 3 easily expands in high withstand well 3 to cause the punch through with ease.

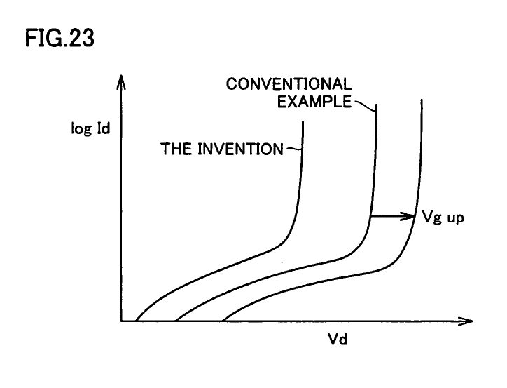

A dependency on a gate voltage of a junction withstand voltage of drain region 11a can be reduced by spacing p-type impurity region 4a from the gate electrode of high withstand voltage transistor of input protection circuit so that, as in the embodiment, p-type impurity region 4a does not reach the side end portion region of drain region 11a. With reference to FIG. 23, description will, then, be given of the reason therefor.

In a case where, as described in Japanese Patent Laying-Open No. 2004-015003, p-type diffused region in contact with the lower portion of n-type drain region is fabricated in the same fabrication step as p-type pocket region, a p-type impurity diffuses and reaches a region in the vicinity of the side end portion region located on the gate electrode side of drain region in formation of p-type diffused region. Hence, a concentration of a p-type impurity in a region in the vicinity of the side end portion region of drain region is raised and not only is a junction withstand voltage of drain region in the region lowered but a potential in the region also easily receives an influence of the gate voltage. Therefore, a junction withstand voltage of drain region changes by altering gate voltage (Vg) as shown in a conventional example of FIG. 23.

In contrast thereto, by preventing p-type impurity region 4a to reach the side end portion region of drain region 11a as in the embodiment, a region low in junction withstand voltage can be intentionally formed only the lower portion of drain region 11a, while it is avoided to increase a concentration of a p-type impurity in substrate located in the vicinity of the end portion of gate electrode. As a result, it is suppressed to reduce a junction withstand voltage in a region in the vicinity of the side end portion region of drain region and it can be avoided, even when the gate voltage is altered, to change a junction withstand voltage of drain region 11a.

Since p-type impurity region 4a shown in FIG. 3 is fabricated in the same fabrication step as low withstand voltage well 4, no necessity arises for a special step to be added for forming p-type impurity region 4a and it is only required to change a mask pattern used in formation of low withstand voltage well 4. Therefore, a semiconductor device can be fabricated in a simple and easy process.

While, in the embodiment, description has been given of the case of NMOS transistor N1 as high withstand voltage transistor, the invention can also be applied to p-MOS transistor as high withstand transistor P1. In this case, the conductivity types of regions or constituents shown in FIG. 3 are reversed.

Low withstand voltage well 4 is formed all over the channel formation region of low withstand voltage transistor LT in a region for forming low withstand voltage transistor LT thereon and different from a pocket region in that low withstand voltage well 4 is formed as far as deep in semiconductor substrate.

### Second Embodiment

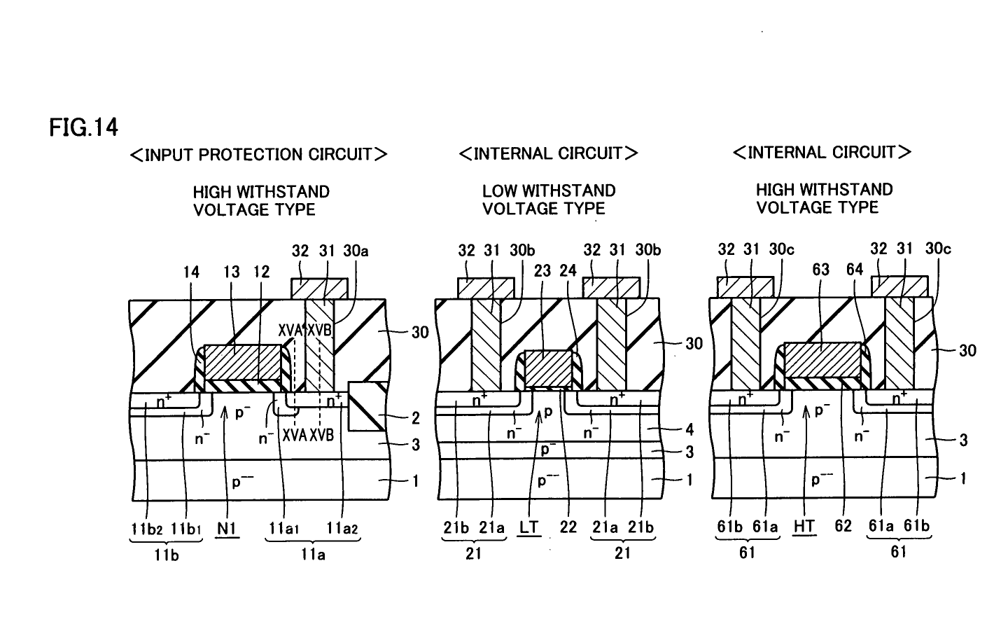

FIG. 14 is schematic sectional views of a high withstand voltage nMOS transistor included in an input protection circuit of a semiconductor device, and a low withstand voltage nMOS transistor and a high withstand voltage nMOS transistor included in a internal circuit of a semiconductor device in the second embodiment of the invention, wherein a sectional view of the high withstand nMOS transistor included in the input protection circuit corresponds to the sectional view taken along line III-III of FIG. 2.

With reference to FIG. 14, p⁻ high withstand well 3 is formed on p⁻⁻ semiconductor substrate in a region for forming a low withstand voltage transistor LT thereon included in the internal circuit and p-type low withstand well 4 is formed on p⁻ high withstand well 3. A pair of n-type impurity regions working as source region 21 and drain region 21, respectively, are formed on a surface of p-type low withstand voltage well 4. A pair of n-type impurity regions 21 and 21 each includes: high concentration region (n-type impurity region) 21 formed on the surface of semiconductor substrate and a low concentration region (n⁻ impurity region) 21a adjacent to the side portion and lower portion of high concentration region 21b, and surrounding high concentration region 21b. A gate electrode 23 is formed on a region sandwiched between a pair of n-type impurity regions 21 with a gate insulating layer 22 interposed therebetween. A sidewall insulating film 24 is formed on the sidewall of gate electrode 23. Low withstand voltage transistor LT is constituted of pair of source/drain regions 21 and 21, gate insulating layer 22 and gate electrode 23.

An interlayer insulating layer 30 is formed so as to cover low withstand voltage transistor LT and contact holes 30b are formed in interlayer insulating layer 30 so as to extend down as far as pair of source/drain regions 21 and 21, respectively. A filling layer 31 is formed in contact holes 30b. A conductive layer 32 is formed on interlayer insulating layer 30 so as to be electrically connected to source/drain regions 21 through filling layer 31.

P⁻ high withstand well 3 is formed on p⁻⁻ semiconductor 1 in a region for forming high withstand voltage transistor HT thereon included in an internal circuit therein. A pair of n-type impurity regions working as the source region 61 and drain region 61, respectively, are formed on a surface of p⁻ high withstand well 3. Pair of n-type impurity regions 61 and 61 each includes: a high concentration region (n-type impurity region) 61b formed on the surface of semiconductor substrate; and a low concentration region (n⁻ impurity region) 61a adjacent to the side portion and lower portion of high concentration region 61b and surrounding high concentration region 61b. A gate electrode layer 63 is formed on a region sandwiched between pair of n-type impurity regions 61 with gate insulating layer 62 interposed therebetween. A sidewall insulating layer 64 is formed on the sidewall of gate electrode layer 63. High withstand voltage transistor HT is constituted of pair of source/drain regions 61 and 61; gate insulating layer 62; and gate electrode layer 63.

Interlayer insulating layer 30 is formed so as to cover high withstand voltage transistor HT and contact holes 30c extending down as far as pair of source/drain regions 61 and 61 are formed in interlayer insulating layer 30. Contact holes 30c are filled with filling layer 31. Conductive layer 32 is formed on interlayer insulating layer 30 so as to be electrically connected to source/drain regions 21 through filling layer 31.

P⁻ high withstand voltage well 3 is formed on p⁻⁻ semiconductor substrate 1 in a region for forming high withstand voltage nMOS transistor (hereinafter referred to as protection circuit nMOS transistor) thereon included in input protection circuit. A pair of n-type impurity regions working as a drain region 11a and source region 11b, respectively, are formed on a surface of p⁻ high withstand voltage well 3.

Source region 11b includes: high concentration region (n-type impurity region) 11b₂ formed on the surface of semiconductor substrate; and a low concentration region (n⁻ impurity region) 11b₁ adjacent to the side portion and lower portion of high concentration region 11b₂ and surrounding the high concentration region 11b₂. Drain region 11a includes: high concentration region (n-type impurity region) 11a₂ formed on the surface of semiconductor substrate; and a low concentration region (n⁻ impurity region) 11a₁ adjacent only to the side portion and lower portion of high concentration region 11a₁.

A gate electrode layer 13 is formed on a region sandwiched between a pair of n-type impurity regions 11a and 11b with gate insulating layer 12. Protection circuit nMOS transistor N1 is constituted of pair of source/drain regions 11a and 11b; gate insulating layer 12; and gate electrode layer 13.

Interlayer insulating layer 30 is formed so as to cover high withstand voltage transistor N1 and contact holes 30a extending down as far as drain region 11a and source region 11b are formed in interlayer insulating layer 30. Contact holes 30a are filled with filling layer 31. Conductive layer 32 is formed on interlayer insulating layer 30 so as to be electrically connected to drain region 11a and source region 11b through filling layer 31.

The surface of semiconductor substrate 1 is electrically isolated with an element isolation structure 2 (for example, a field oxide film, a trench isolation with a structure in which trenches are filled with insulating layer).

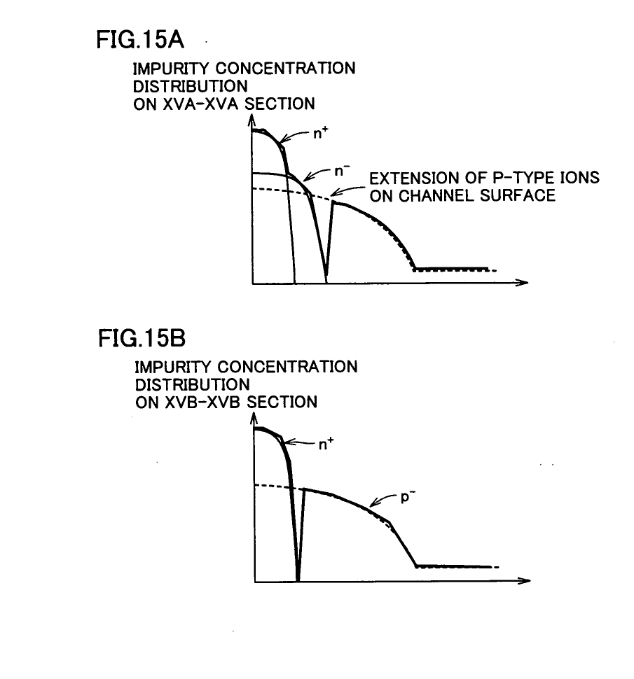

FIG. 15A is a graph showing an impurity concentration distribution on section taken along line of XVA-XVA of FIG. 14 and FIG. 15B is a graph showing an impurity concentration distribution on section taken along line of XVB-XVB of FIG. 14.

Since low concentration region 11a₁ is formed in the end portion on the source side of high concentration region 11a₂, an impurity concentration distribution in a pn junction section between drain region 11a and p⁻ high withstand voltage well 3 in the end portion on the source side is comparatively gentle as shown FIG. 15A. On the other hand, since no low concentration region 11a is formed in the vicinity of the other portion (the lower portion region of drain region 11a), high concentration region 11a₂ is adjacent directly to p⁻ high withstand voltage well 3. Hence, an impurity concentration distribution in a pn junction section between drain region 11a in the portion and p⁻ high withstand voltage well 3 is comparatively steep. Hence, drain region 11a has a construction that the end portion on the source side is higher in withstand voltage than the other portion.

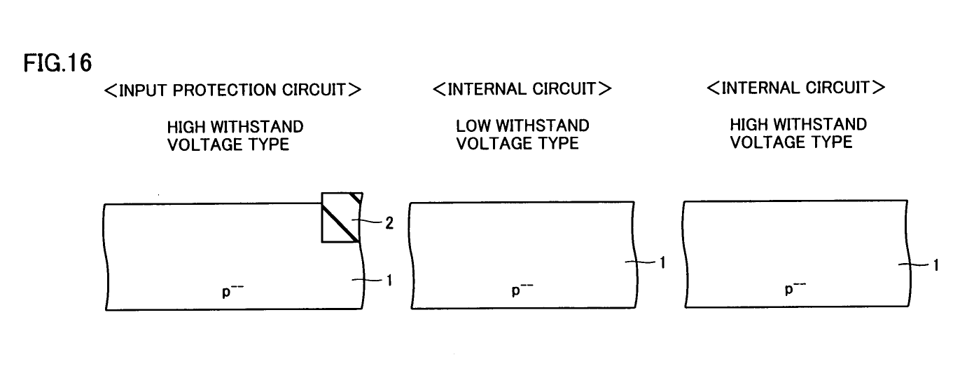

Then, description will be given of a fabrication method of the embodiment. FIGS. 16 to 22 are schematic sectional views showing a fabrication method, in the order of steps in which operations occur, of the second embodiment of the invention. With reference to FIG. 16, element isolation structure 2 is formed on the surface of p⁻⁻ semiconductor substrate 1.

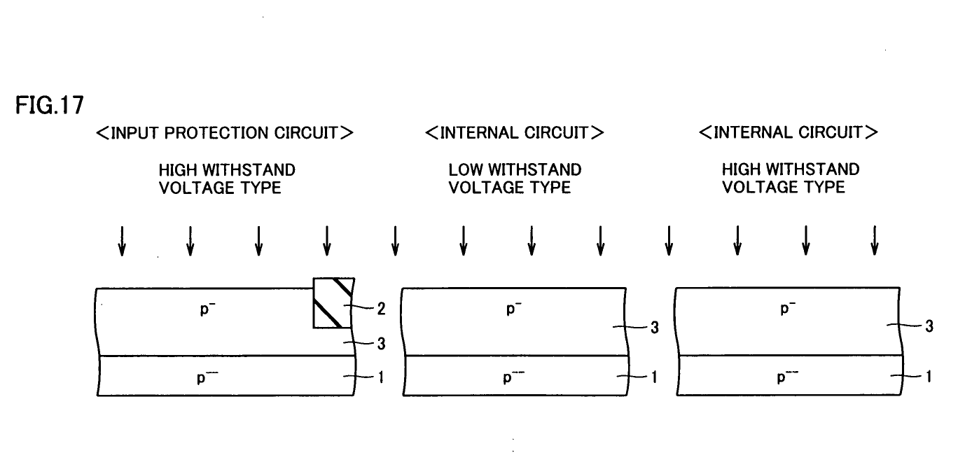

With reference to FIG. 17, p⁻ high withstand voltage wells 3 are formed in a region for forming protection circuit NMOS transistor thereon, a region for forming low withstand voltage transistor thereon and a region for forming low withstand transistor thereon. In formation of p⁻ high withstand voltage well 3, for example, boron (B) is ion implanted at an implantation energy in the range of from 70 to 120 keV and a dose 2×10¹² cm⁻² or less to adjust a punch through effect and secure isolation ability and thereafter, boron is ion implanted at an implantation energy in the range of from 30 to 60 keV and a dose of 21×10¹² cm⁻² or less to adjust a threshold voltage of a transistor.

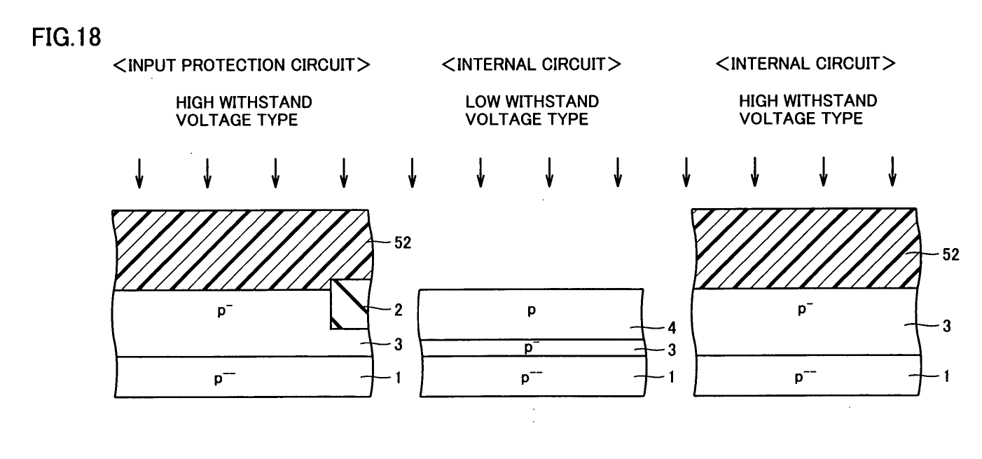

With reference to FIG. 18, a photoresist pattern 52 is formed with a photolithography technique on semiconductor substrate and p-type impurity is introduced into semiconductor substrate, for example, by ion implantation or the like with a pattern 52 as a mask. In this step, p-type low withstand well 4 is formed in a region for forming low withstand voltage transistor therein. In formation of low withstand voltage well 4, for example, boron (B) is ion implanted at an implantation energy in the range of from 70 to 120 keV and a dose 3×10¹² cm⁻² or less to adjust a punch through effect and secure isolation ability and thereafter, boron is ion implanted at an implantation energy in the range of from 30 to 60 keV and a dose of 1×10¹³ cm⁻² or less to adjust a threshold voltage of a transistor. Thereafter, pattern 52 is removed, for example, by ashing.

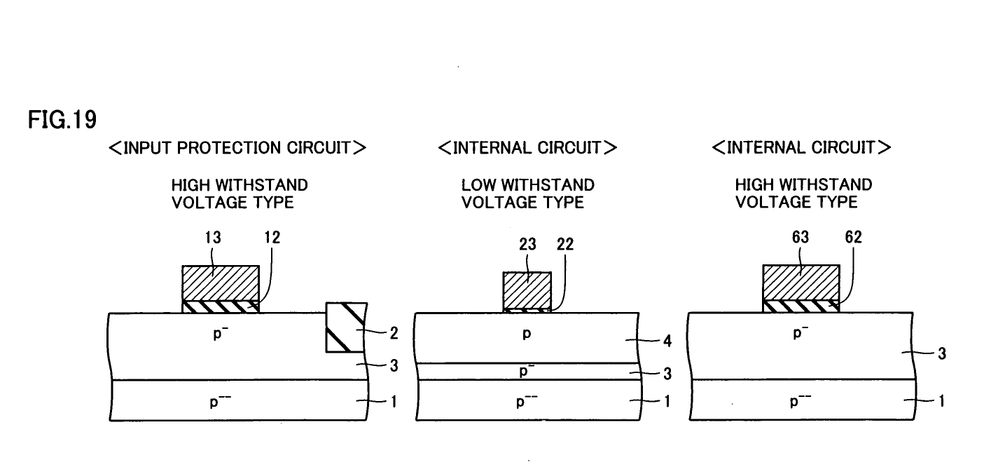

With reference to FIG. 19, gate electrode layers 13, 23 and 63 are formed in regions for forming protection circuit nMOS transistor, low withstand voltage transistor and high withstand voltage transistor, respectively, thereon with gate insulating layers 12, 22 and 62 interposed therebetween. In the embodiment as well, widths of gate electrode layers 13 and 63 of high withstand voltage transistors are designed so as to be larger than a width of gate electrode layer 23 of low withstand voltage transistor and thickness values of gate insulating layers 12 and 62 of high withstand voltage transistors are designed so as to be larger than a thickness value of gate insulating layer 22 of low withstand voltage transistor.

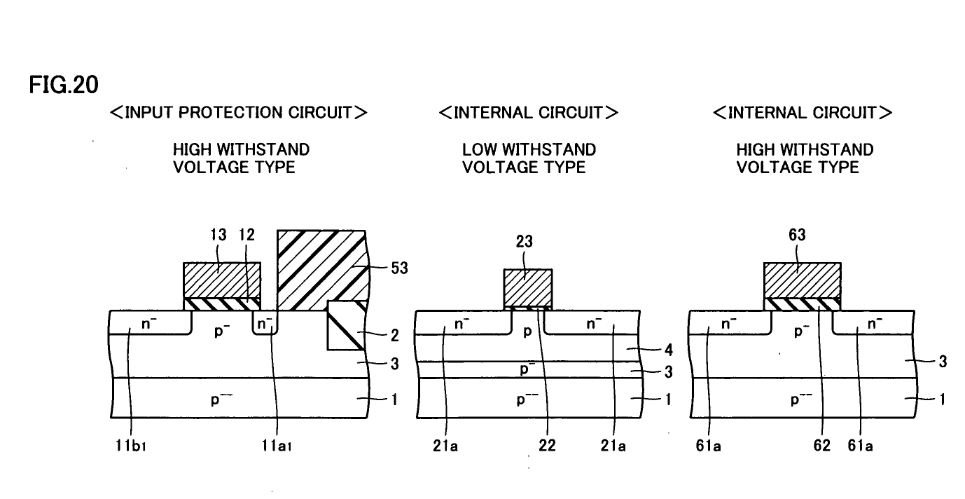

With reference to FIG. 20, an n-type impurity is introduced into semiconductor substrate, for example, by ion implantation or the like with gate electrode layers 13, 23 and 63, and photoresist pattern 53 formed by a photolithography technique or the like as a mask. In this step, n-type low concentration regions 11a₁ and 11b₁ are formed in a region for forming protection circuit nMOS transistor thereon, n-type low concentration regions 21a and 21a are formed in a region for forming low withstand voltage transistor thereon and n-type low concentration regions 61a and 61a are formed in a region for forming high withstand voltage transistor thereon. Thereafter, pattern is removed, for example, by ashing. In this situation, low concentration region 11a₁ of a region for forming protection circuit NMOS transistor thereon is formed only in the vicinity of gate electrode layer 13.

Note that while, in the above example, description has been given of a case where low withstand voltage low concentration regions 21a and 21a, high withstand voltage low concentration regions 11a₁ and 11b₁ and low concentration regions 61a and 61a are simultaneously fabricated, the regions may be formed in different ion implantation steps. In the latter case, for formation of high withstand voltage low concentration regions 11a₁ and 11b₂ and low concentration regions 61a and 61a, for example, phosphorus (P) is ion implanted at an implantation energy in the range of 20 to 50 keV and a dose of 1×10¹³ cm⁻² or more and 3×10¹³ cm⁻² or less, followed by a heat treatment for diffusion. In a case where low withstand voltage type low concentration regions 21a and 21a are formed, for example, arsenic (As) is ion implanted at an implantation energy in the range of from 20 to 50 keV and at a dose of 1×10¹⁴ cm⁻² or more and 5×10 cm⁻² or less.

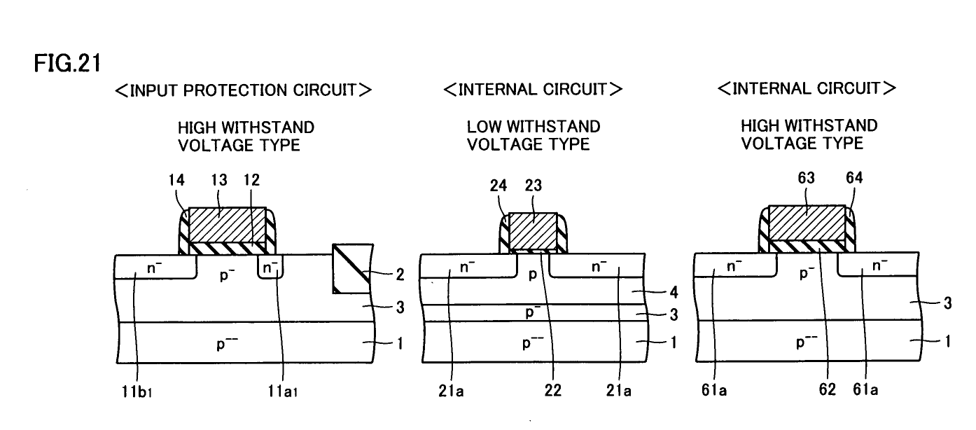

With reference to FIG. 21, sidewall insulating layers 14, 24 an 64 are formed on the sidewall of gate electrode layer 13, 23 and 63.

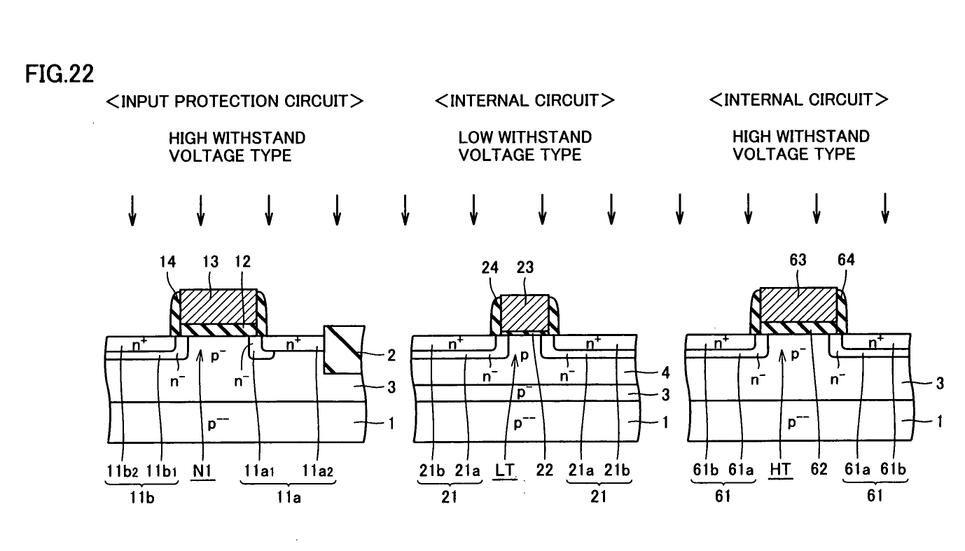

With reference to FIG. 22, an n-type impurity is introduced into semiconductor substrate, for example, by ion implantation or the like with gate electrode layers 13, 23 and 63 and sidewall insulating layer 14, 24 and 64 as a mask. Thereby, n-type high concentration regions 11a₂ and 11b₂ are formed in a region for forming protection circuit nMOS transistor thereon, n-type high concentration regions 21b and 21b are formed in a region for forming low withstand voltage transistor thereon and n-type high concentration regions 61b and 61b are formed in a region for forming high withstand voltage transistor thereon. In formation of high concentration regions 11a₂ and 11b₂, high concentration regions 21b and 21b and high concentration regions 61b and 61b, for example, arsenic (As) is ion implanted at an implantation energy in the range of from 30 to 50 keV and a dose of 1×10¹⁵ cm⁻² or more and 5×10¹⁵ cm⁻² or less.

In this step, in regions for forming low withstand voltage transistor and high withstand voltage transistor thereon, high concentration regions 21b an 61b are formed so that low concentration regions 21a and 61a are adjacent to the side end potions and lower portions of high concentration regions 21b and 61b and surrounding high concentration regions 21b an 61b.

In a region for forming protection circuit nMOS transistor thereon, high concentration region 11b₂ is formed so that low concentration region 11b₁ is adjacent to the side portion and lower portion of high concentration region 11b₂ and surrounding high concentration region 11b₂. High concentration region 11a₂ is formed so that low concentration region 11a₁ is adjacent only to the side end portion and lower portion on the source side of high concentration region 11a₂.

Thereafter, interlayer insulating layer 30, filling layer 31, conductive layer 32 and others shown in FIG. 4 are formed to thereby complete a semiconductor device of the embodiment.

According to the embodiment, as shown in FIGS. 14 and 15, no low concentration region 11a₁ is formed except for the end portion (the side end portion region located on the gate electrode side) on the source side of high concentration region 11a₂ in a region for forming protection circuit nMOS transistor thereon and high concentration region 11a₂ except for the end portion on the source side is adjacent directly to p⁻ high withstand voltage well 3. Hence, an impurity concentration distribution in a pn junction section between drain region 11a and p⁻ high withstand well 3 in this portion except for the end portion on the source side is comparative steep and a junction withstand voltage of drain region 11a is lower in the portion except for the end portion on the source side than in the end portion on the source side. Therefore, in this embodiment as well in a similar way to that in the first embodiment, a withstand voltage in the junction section between high concentration region 11a₂ and p⁻ high withstand voltage well 3 can be lower than that in the junction section between low concentration region 11a₁ in the end portion on the source side and p⁻ high withstand voltage well 3. Thereby, when a surge voltage is applied, electron-hole pairs can be generated in the junction section between high concentration region 11a₂ and p⁻ high withstand voltage well 3 at a voltage lower than a withstand voltage of the gate end portion and occurrence of electron-hole pairs in drain region 11a of the gate end portion can be prevented. A parasitic bipolar transistor can be turned on with electron-hole pairs generated at the low voltage. Therefore, injection of carriers into the gate insulating layer of input protection circuit can be suppressed with the result that occurrence of minute leakage current due to the GIDL can be suppressed.

Since high withstand voltage well 3 lower in concentration of a p-type impurity than low withstand voltage 4 is located right below a channel formation region in which punch through actually occurs, a depletion layer can easily expand in high withstand voltage well 3 to cause the punch through with ease.

In the second embodiment as well, a region low in junction withstand voltage can be intentionally formed below the drain region 11a while it is avoided to raise a concentration of a p-type impurity in substrate located in the vicinity of the side end portion region of drain region 11a located on the gate electrode side. Therefore, in a similar way to that in the first embodiment, a change in a junction withstand voltage of drain region 11a can be avoided even when a gate voltage is altered.

In addition, no necessity arises for a specific step to be added in order form high concentration region 11a₂ in a region for forming protection circuit nMOS transistor thereon shown in FIG. 14 and it is only required to alter a pattern of a mask when another high concentration region 11b₂ or the like is formed. Therefore, a semiconductor device can be fabricated in a simple and easy process.

While, as described above, the embodiments of the invention have been presented, it is also expected, from the beginning of the description, that constructions of the embodiments can be appropriately combined.

It should be considered that the embodiments having been disclosed this time are by way of illustration in every regard thereof and not to be taken by way of limitation. The invention should be construed within meets and bounds of the claims and all changes and modifications falls in the meets and bounds of the claims and equivalence thereof.

Although the present invention has been described and illustrated in detail, it is clearly understood that the same is by way of illustration and example only and is not to be taken by way of limitation, the spirit and scope of the present invention being limited only by the terms of the appended claims.

1. A semiconductor device having an input protection circuit disposed between an input/output terminal and an internal circuit, comprising:
a first conductivity type substrate having a main surface;
a high withstand voltage transistor, included in said input protection circuit, formed on the main surface of said substrate, and having a source region and a drain region of a second conductivity type; and
a low withstand voltage transistor, included in said internal circuit, formed on the main surface of said substrate, and having a source region and a drain region of the second conductivity type, wherein
the drain region of said high withstand voltage transistor has a side end portion region located on the gate electrode side of the high withstand voltage transistor and a lower portion region spaced from said gate electrode more than the side end portion region, and
a junction withstand voltage between a first conductivity type first region adjacent to said lower portion region and said lower portion region is reduced to a value lower than a junction withstand voltage between a first conductivity type second region adjacent to said side end portion region and said side end portion region.

2. The semiconductor device according to claim 1, wherein
a concentration of a first conductivity type impurity included in said first region is higher than a concentration of the first conductivity impurity included in said second region.

3. The semiconductor device according to claim 2, wherein
said high withstand voltage transistor is formed on a first conductivity first well formed on the main surface of said substrate,
said low withstand voltage transistor is formed on the main surface of said substrate and formed on a first conductivity type second well higher in concentration than said first well, and
a concentration of the first conductivity impurity included in said first region is substantially equal to a concentration of the first conductivity type impurity included in said second well.

4. The semiconductor device according to claim 1, wherein
a concentration of a second conductivity impurity in a portion adjacent to said second region in said side end portion region is lower than a concentration of the second conductivity impurity in a portion adjacent to said first region in said lower portion region.

5. A semiconductor device having an input protection circuit disposed between an input/output terminal and an internal circuit, comprising:
a first conductivity type substrate having a main surface;
a high withstand voltage transistor included in said input protection circuit, formed on the main surface of said substrate, and having a source region and a drain region of a second conductivity type;
a low withstand voltage transistor, included in said internal circuit, formed on the main surface of said substrate, and having a source region and a drain region of the second conductivity type; and
a first conductivity type impurity region adjacent to the drain region of said high withstand voltage transistor, wherein
the drain region of said high withstand voltage transistor has a side end portion region located on the gate electrode side of the high withstand voltage transistor and a lower portion region spaced from said gate electrode more than the side end portion region,
a concentration of a first conductivity type impurity included in said impurity region is higher than a concentration of the first conductivity impurity included in a first conductivity type region adjacent to said side end portion region,
said impurity region is formed so as to be adjacent to said lower portion region without reaching said side end portion region, and
an end portion of said impurity region located on the gate electrode side of said high withstand transistor is positioned apart from the gate electrode of said high withstand transistor so as not to overlap the gate electrode thereof.

6. The semiconductor device according to claim 5, wherein
said high withstand voltage transistor has a sidewall insulating layer on a sidewall of the gate electrode, and
an end portion of said impurity region located on the gate electrode side of said high withstand voltage transistor is positioned apart from the sidewall insulating layer so as not to overlap said sidewall insulating layer.

7. A semiconductor device having an input protection circuit disposed between an input/output terminal and an internal circuit, comprising:
a substrate having a main surface;
a first conductivity type first well formed on the main surface of said substrate;
a first conductivity type second well, formed on the main surface of said substrate and higher in concentration of a first conductivity impurity than said first well;
a high withstand voltage transistor, included in said input protection circuit, and having a source region and a drain region of a second conductivity formed on said first well;
a low withstand voltage transistor included in said internal circuit, and having a source region and a drain region of the second conductivity formed on said second well; and
a first conductivity type impurity region formed in the same fabrication step as said second well so as to be adjacent to a lower portion of said drain region of said high withstand voltage transistor.

8. A semiconductor device having an input protection circuit disposed between an input/output terminal and an internal circuit, comprising:
a substrate having a main surface;
a first conductivity type first well formed on the main surface of said substrate; and
a high withstand voltage transistor, included in said input protection circuit, and having a source region and a drain region of a second conductivity formed on said first well, wherein
said source region of said high withstand voltage transistor has a second conductivity type high concentration region formed on the main surface of said substrate and a low concentration region, adjacent to side and lower portions of said high concentration region, and surrounding the high concentration region, and
said drain of said high withstand voltage transistor has a second conductivity type high concentration region formed on the main surface of said substrate and the low concentration region adjacent only to the side and lower portions of an end portion on said source side of said high concentration region.

9. The semiconductor device according to claim 8, further comprising:
a high withstand voltage transistor included in said internal circuit, wherein
a source region and a drain region of said high withstand voltage transistor included in said internal circuit have, respectively, high concentration regions formed on the main surface of said substrate and low concentration regions adjacent to the side portions and lower portions of said high concentration regions and surrounding the high concentration regions, respectively.

10. The semiconductor device according to claim 1, further comprising:
a first conductivity annular impurity region surrounding the high withstand voltage transistor included in said input protection circuit; and
a ground electrode giving ground potential to said annular impurity region.

11. A fabrication method for a semiconductor device having an input protection circuit disposed between an input/output terminal and an internal circuit, comprising the steps of:
forming a first conductivity type first well on a main surface of a substrate;
not only forming a first conductivity type second well higher in concentration of a first conductivity type impurity than in said first well on the main surface of said substrate, but also forming a first conductivity type impurity region in said first well in the same fabrication step as said second well; and
forming source and drain regions of a second conductivity type of a low withstand voltage transistor included in said internal circuit in said second well and source and drain regions of the second conductivity type of a high withstand voltage transistor included in said input protection circuit in said first well, wherein
said drain region of said high withstand voltage transistor is formed so that said impurity region is adjacent to the lower portion of said drain region of said high withstand voltage.

12. A fabrication method for a semiconductor device having an input protection circuit disposed between an input/output terminal and an internal circuit, comprising the steps of:
forming a first conductivity type first well on a main surface of a substrate;
forming a gate electrode layer on the main surface of said substrate with a gate insulating layer interposed therebetween;
introducing an impurity into the main surface of said substrate with said gate electrode layer as a mask to thereby form a pair of low concentration regions of a second conductivity type working as source and drain regions of a high withstand voltage transistor included in said input protection circuit in said first well;
forming a sidewall insulating layer on a side surface of said gate electrode layer; and
introducing an impurity into the main surface of said substrate with said gate electrode layer, said sidewall insulating layer and a mask pattern as a mask to thereby form a pair of high concentration regions of the second conductivity type working as said source and drain regions in said first well, wherein
said high concentration region of said source region is formed so as to be surrounded with said low concentration region at the side and lower portions of said high concentration, and
said high concentration region of said drain region is formed so as to be surrounded with said low concentration region only at the side and lower portions of an end portion on the source side of said high concentration region.

13. The fabrication method for a semiconductor device according to claim 12, wherein
a pair of second conductivity type low concentration regions working as a source region and a drain region of a high withstand voltage transistor included in said internal circuit are fabricated in the same fabrication step as the pair of second conductivity type low concentration regions working as said source region and drain region of said high withstand voltage transistor included in said input protection circuit,
a pair of second conductivity type high concentration regions working as the source region and drain region of said high withstand voltage transistor included in said internal circuit are fabricated in the same fabrication step as the pair of second conductivity type high concentration regions working as said source region and drain region of said high withstand voltage transistor included in said input protection circuit, and
said low concentration regions of said source region and drain region of said high withstand voltage transistor included in said internal circuit are formed adjacent to the side portion and lower portion of said high concentration regions so as to surround said high concentration regions.
